(19) United States
(12) Patent Application Publication
(10) Pub. No.: US 2026/0235689 A1
(43) Pub. Date: Aug. 13, 2026

(54) SYSTEM AND METHOD FOR ELECTRIC VEHICLE (EV) FLEET MANAGEMENT

(71) Applicant: Honeywell International Inc., Charlotte, NC (US)

(72) Inventors: Shruti Verma, Pune (IN); Magesh Lingan, Bangalore (IN); Gaurav Agarwal, Leander, TX (US); Madhav Kamath, Bangalore (IN); Ramanjaneyulu Karnati, Palnadu (IN); Sambit Mohanty, Cuttack (IN); Deepthi Sethuraman, Bangalore (IN); Pratiksha Deshpande, Chalisgaon (IN)

(21) Appl. No.: 19/051,299

(22) Filed: Feb. 12, 2025

(51) Int. Cl. G01R 31/392; G01R 31/382

(52) U.S. Cl. CPC G01R 31/392; G01R 31/382

(57) ABSTRACT

Various embodiments described herein relates to monitor state of health (SoH) and residual life of the electric vehicle (EV) battery. In this regard, data corresponding to one or more parameters related to the EV battery is acquired, wherein the EV battery is associated with a corresponding electric vehicle (EV). Further, the data associated with the EV battery is aggregated at a fleet monitoring cloud platform. As a result, a measured capacity of the EV battery is calculated based on the aggregated data. Also, a usable original capacity of the battery is determined, wherein the usable original capacity indicates an initial maximum capacity of the EV battery. Further, a current state of health (SoH) of the battery is determined based on the measured capacity and the usable original capacity of the battery. Also, the residual life of the battery is determined based on a degradation rate of the battery and the current state of health (SoH) of the battery.

### TECHNICAL FIELD

The present disclosure is related to the field of electric vehicle (EV) fleet management and, more particularly, to a system and method for monitoring state of health (SoH) and residual life of EV batteries within EV fleets through Original Equipment Manufacturer (OEM) telematics system, utilizing advanced data-driven techniques and machine learning models.

### BACKGROUND

Electric vehicles (EVs) have become a cornerstone of the automotive industry's shift toward sustainable and eco-friendly transportation. EVs are getting more popularity due to stringent government norms and the depletion of internal combustion (IC) engines fuel resources. The EV market grew from 4% to 18% in 2023, reaching 14 million vehicles (a 35% annual increase). Unlike traditional vehicles that rely on IC engines powered by fossil fuels, EVs are powered by electric motors, which draw energy from rechargeable battery packs. This shift to electric propulsion offers numerous environmental benefits, including the reduction of greenhouse gas emissions, improved air quality, and decreased dependence on oil. As the demand for EVs grows, innovations in battery technology have played a key role in making these EVs more efficient, practical, and accessible. The heart of most modern EVs is the lithium-ion (Li-ion) battery, a rechargeable energy storage system that provides the power necessary for driving the EVs. Li-ion batteries are favored in the EV industry due to their high energy density, lightweight nature, and relatively long lifespan compared to other types of batteries.

With the increasing adoption of EVs, fleet operators face challenges in managing the state of health of EV batteries. A battery's performance and longevity are influenced by numerous factors, including charging cycles, depth of discharge, voltage, temperature, and overall usage. Although basic parameters such as state of charge (SoC) and energy levels are readily available, current solutions do not provide comprehensive insights into the actual health or residual life of the battery, which are crucial for fleet operators to optimize maintenance schedules, reduce operational costs, and extend battery lifespan. Existing systems do not offer a straightforward method to infer battery health or predict residual life based on available data, such as charging and discharging patterns, battery temperature, and voltage. Therefore, there is a need for a more advanced and integrated solution capable of accurately assessing battery health and predicting the remaining useful life of EV batteries.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments, in which:

FIG. 1 illustrates a schematic diagram illustrating an Electric Vehicle (EV) fleet management system managing a plurality of EVs in accordance with one or more embodiments of the present disclosure;

FIG. 2 is a schematic diagram illustrating an implementation of a controller of the EV fleet management system that may execute techniques in accordance with one or more embodiments of the present disclosure;

FIG. 3 is an exemplary block diagram illustrating an implementation of the EV fleet management system, in accordance with one or more embodiments of the present disclosure;

FIG. 4 is an exemplary block diagram illustrating monitoring state of health (SoH) of EV batteries in accordance with one or more embodiments of the present disclosure; and

FIG. 5 is a flowchart illustrating a method described in accordance with one or more embodiments of the present disclosure.

### SUMMARY

The details of some embodiments of the subject matter described in this specification are set forth in the accompanying drawings and the description below. Other features, aspects, and advantages of the subject matter will become apparent from the description, the drawings, and the claims.

In accordance with an embodiment of the present disclosure, a system for monitoring state of health (SoH) and residual life of the electric vehicle (EV) battery is described herein. The system comprises at least one processor and a memory communicatively coupled to the at least one processor. The memory comprises one or more instructions which when executed by the at least one processor, cause the processor to acquire data corresponding to one or more parameters related to each of a plurality of batteries, wherein each of the plurality of batteries is associated with a corresponding electric vehicle (EV) of a plurality of electric vehicles (EVs), aggregate the data associated with each of the plurality of batteries at a fleet monitoring cloud platform, calculate a measured capacity of a battery of the plurality of batteries based on the aggregated data, determine a usable original capacity of the battery, wherein the usable original capacity indicates an initial maximum capacity of the battery, and determine a current state of health (SoH) of the battery based on the measured capacity and the usable original capacity of the battery.

In accordance with an example embodiment, a method for monitoring state of health (SoH) and residual life of the electric vehicle (EV) battery is described herein. The method comprises acquiring data corresponding to one or more parameters related to each of a plurality of batteries, wherein each of the plurality of batteries is associated with a corresponding electric vehicle (EV) of a plurality of electric vehicles (EVs), aggregating the data associated with each of the plurality of batteries at a fleet monitoring cloud platform, calculating a measured capacity of a battery of the plurality of batteries based on the aggregated data, determining a usable original capacity of the battery, wherein the usable original capacity indicates an initial maximum capacity of the battery, and determining a current state of health (SoH) of the battery based on the measured capacity and the usable original capacity of the battery.

The above summary is provided merely for purposes of providing an overview of one or more exemplary embodiments described herein so as to provide a basic understanding of some aspects of the disclosure. Accordingly, it will be appreciated that the above-described embodiments are merely examples and should not be construed to narrow the scope or spirit of the disclosure in any way. It will be appreciated that the scope of the disclosure encompasses many potential embodiments in addition to those here summarized, some of which are further explained in the following description and its accompanying drawings.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### DETAILED DESCRIPTION

Reference will now be made in detail to embodiments, examples of which are illustrated in the accompanying drawings. In the following detailed description, numerous specific details are set forth in order to provide a thorough understanding of the various described example embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments. The term “or” is used herein in both the alternative and conjunctive sense, unless otherwise indicated. The terms “illustrative,” “example,” and “exemplary” are used to be examples with no indication of quality level. Like numbers refer to like elements throughout.

The phrases “in an embodiment,” “in one embodiment,” “according to one embodiment,” and the like generally mean that the particular feature, structure, or characteristic following the phrase may be included in at least one example embodiment of the present disclosure, and may be included in more than one example embodiment of the present disclosure (importantly, such phrases do not necessarily refer to the same example embodiment).

The word “exemplary” is used herein to mean “serving as an example, instance, or illustration.” Any implementation described herein as “exemplary” is not necessarily to be construed as preferred or advantageous over other implementations. If the specification states a component or feature “can,” “may,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some example embodiments, or it may be excluded.

Electric vehicles (EVs) have gained significant traction as a sustainable and environmentally friendly alternative to traditional vehicles that rely on internal combustion engines powered by fossil fuels. As the adoption of EVs continues to grow, one of the key challenges that vehicle owners, fleet operators, and manufacturers face is the management and monitoring of the health of EV batteries. The battery is the most crucial and expensive component of an EV, and its performance directly influences the vehicle's range, efficiency, and longevity. EV batteries, particularly lithium-ion (Li-ion) batteries, degrade over time due to various factors such as charging cycles, temperature variations, and usage patterns. As batteries age, their capacity diminishes, meaning the EV can travel shorter distances on a single charge and may experience reduced performance. This degradation can significantly affect the overall reliability and operational efficiency of electric vehicles.

Battery degradation occurs due to complex interactions between multiple factors, including deep discharges, overcharging, exposure to high or low temperatures, and improper charging practices. However, accurately predicting the rate of degradation and determining the remaining useful life of a battery is a highly complex task. Existing systems generally focus on short-term metrics, such as the state of charge (SoC) or voltage levels, which do not provide a comprehensive understanding of the battery's long-term health. This lack of insight can lead to unexpected failures or suboptimal performance of EV batteries, causing inconvenience to owners and leading to unplanned maintenance for fleet operators. Furthermore, traditional battery management systems (BMS), which are typically found within individual vehicles, monitor only basic parameters such as charge, temperature, and current, without offering much in terms of long-term health monitoring or predictive analytics that could inform future battery performance.

The inability to predict the remaining useful life of an EV battery is a significant challenge for both individual owners and fleet managers. The useful lifespan of a battery varies widely depending on factors such as driving habits, frequency of charging, and environmental conditions. Fleet operators managing large numbers of EVs often rely on general estimations or manufacturer guidelines to determine when to replace batteries, but these methods lack personalization and fail to account for real-world usage variations. Furthermore, different vehicle manufacturers and battery chemistries can exhibit different degradation rates, making it difficult to apply a one-size-fits-all approach to battery health monitoring across a mixed fleet. Without accurate predictions of battery health and residual life, fleet operators are often left in the dark regarding the optimal time for maintenance or replacement, potentially leading to costly downtime and reduced vehicle performance.

Safety is another major concern associated with EV batteries. Overcharging, overheating, and thermal runaway are well-documented risks that can lead to catastrophic failures such as fires or explosions. While modern battery systems are equipped with protective mechanisms to prevent such issues, these events are still a significant concern for manufacturers, fleet operators, and consumers alike. Current systems generally monitor individual parameters like voltage and temperature but do not offer integrated solutions to detect early warning signs or predict when the battery might be at risk of safety issues. A system that can predict potential failures or hazardous conditions based on a comprehensive analysis of real-time data is essential for ensuring battery safety.

Moreover, the fragmentation of EV fleet management tools is a prevalent issue in the industry. Different manufacturers may offer proprietary telematics and fleet management solutions that are not compatible with one another. This makes it difficult for fleet managers who operate a diverse set of vehicles from multiple manufacturers to obtain a unified view of battery health, usage patterns, and performance data. These siloed systems result in inefficiencies and missed opportunities for optimizing fleet performance, maintenance schedules, and battery life.

Additionally, the charging process itself plays a crucial role in the degradation of EV batteries. Overcharging, frequent fast charging, and high-temperature charging can all accelerate the wear and tear on the battery. However, there are no systems in place that integrate real-time battery health data to predict the most optimal charging times and strategies for individual vehicles based on their specific battery state and usage profile. Optimizing the charging schedule not only prolongs the life of the battery but also ensures that EVs remain operationally efficient without unnecessarily high charging costs.

Currently, there are multiple software systems like Charge management software, Vehicle telematic system, and Battery management system to monitor EV charging operations. These systems are mostly used in silos for monitoring purposes and lack optimization capabilities. These systems lack the capability to infer battery health and/or predict residual life based on available data, such as EV port status, current power, energy overview, dynamic load management, charging and discharging patterns, battery temperature, and voltage. Traditional EV manager lacks access to fleet vehicle traction battery data and OEM telematics, including lithium battery KPIs. The shortcomings of existing battery monitoring and fleet management systems highlight the need for a more comprehensive, predictive, and integrated solution that can accurately track battery health over time, monitor remaining useful life, optimize charging strategies, and detect early warning signs of potential safety issues. Therefore, there is a need for a more advanced and integrated solution capable of accurately assessing battery health and predicting the remaining useful life of EV batteries (i.e. Li-ion batteries). Such a system would enable fleet operators to make more informed decisions regarding battery maintenance and replacements, enhancing the overall efficiency and sustainability of their EV operations.

To address the above issues, the present invention provides a fleet monitoring cloud platform capable of aggregating data from a diverse range of EVs, regardless of manufacturer, and applying custom calculations and advanced artificial intelligence (AI) and machine learning (ML) techniques to determine state of health (SoH) and performance of electric vehicle (EV) batteries within a fleet of EVs, predict battery degradation, estimate residual life of the battery, and optimize charging and maintenance schedules. By aggregating a wide range of key lithium battery parameters such as state of charge (SoC), temperature, voltage fluctuations, and charging/discharging patterns, the present invention is capable of accurately assessing the current state of health (SoH) of each battery. The present invention compares the measured capacity of each battery to its original usable capacity to determine the current state of health (SoH) of each battery. The present invention allows for real-time monitoring and fleet-wide insights, helping fleet operators to make more informed decisions and ensuring the longevity, safety, and efficiency of their EV fleet.

One of the key features of the invention is its ability to predict the residual life of each battery in the fleet, using artificial intelligence (AI) and machine learning (ML) models that analyze historical performance data and degradation patterns. These predictive models help forecast when a battery is likely to fail or when it will require maintenance, enabling fleet operators to take proactive measures, optimize replacement schedules, and minimize unplanned downtimes. The system also monitors the charging process in real-time, calculating the energy transferred and using this information to refine the measurement of battery capacity, which ultimately supports more accurate health assessments.

In addition to battery health and residual life predictions, the invention also addresses safety concerns related to overcharging, overheating, and thermal runaway by incorporating real-time sensor data to detect potential hazards. When such issues are identified, the present invention enables generation of alerts to prevent dangerous situations. Furthermore, the present invention allows fleet managers to track battery performance across an entire fleet, offering a unified dashboard view of the health, usage, and maintenance status of all vehicles, regardless of their make or model. The present invention also includes predictive maintenance capabilities, ensuring that operators can anticipate and address battery issues before they result in failure. The seamless integration with existing vehicle telematics systems allows for real-time insights into battery performance and optimized charging schedules, which help prolong battery life and reduce operational costs. The present invention not only offers a way to monitor and optimize battery health but also provides essential information for making data-driven decisions to enhance the efficiency, safety, and longevity of EV fleets.

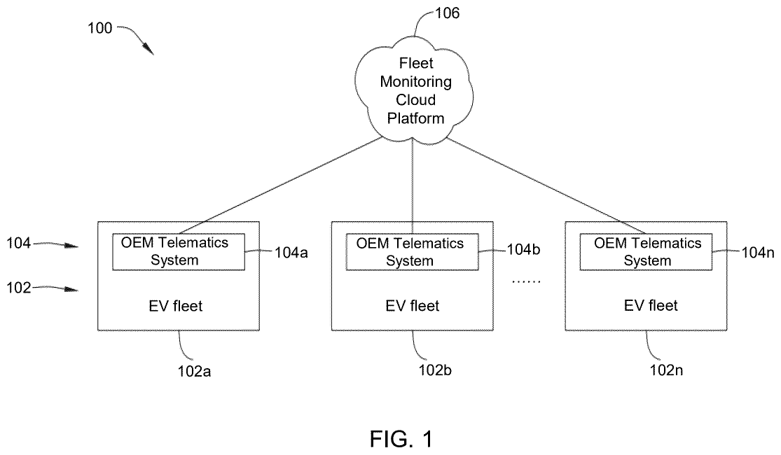

FIG. 1 illustrates a schematic diagram of an Electric Vehicle (EV) fleet management system 100, which manages and monitors multiple electric vehicles (EVs) within EV fleets in accordance with one or more example embodiments described herein. According to various example embodiments described herein, the exemplary EV fleet management system 100 comprises multiple fleets of EVs 102a, 102b, . . . 102n (collectively “EV fleets 102”) from different Original Equipment Manufacturers (OEMs). In some example embodiments, the one or more EV fleets 102 in the illustrative system 100 may be of same type. In some example embodiments, the one or more EV fleets in the illustrative system 100 may be of different type. As it may be understood, in some example embodiments described herein, each of the EV fleets 102 often include one or more EVs.

Each OEM includes a respective OEM telematics system 104a, 104b, . . . 104n (collectively “OEM telematics systems 104”). Per this aspect, the OEM telematics systems 104 collect data associated with the one or more EVs, including battery data, charging cycles, temperature variations, and voltage changes during both charging and discharging phases. Different EV fleets 102 may consist of EVs from different OEMs. Therefore, the EV fleet management system 100 is designed to handle data from diverse OEM telematics systems 104. The OEM telematics systems 104 from each manufacturer may differ in terms of data format, protocol, or transmission method. However, the EV fleet management system 100 is capable of aggregating and normalizing this data, making it possible to compare and analyze the performance of batteries across different EV models and manufacturers. The EVs could be, but not limited to, cars, trucks, buses, vans, motorcycles, scooters, tractors, and/or the like.

Further, in one or more example embodiments described herein, each EV in the EV fleets 102 is equipped with one or more sensors and telemetry system that provide data regarding the EV battery's performance, such as charging patterns, temperature, voltage, and state of charge (SoC). In accordance with some example embodiments, the one or more sensors are employed in the EV to sense the data associated with the EV battery. In accordance with some example embodiments, the one or more sensors is communicatively coupled with the OEM telematics system 104 of the EV fleet 102. Accordingly, the OEM telematics system 104 of the EV fleet 102 receives the data associated with the one or more EV batteries via the one or more sensors. In addition, in some example embodiments, the OEM telematics system 104 processes the data received from the one or more sensors to derive insights associated with each of the one or more EV batteries.

Further, in some example embodiments, the one or more EV fleets 102 may be operably coupled with a fleet monitoring cloud platform 106, meaning that communication between the fleet monitoring cloud platform 106 and the one or more EV fleets 102 is enabled. In some example embodiments, the one or more OEM telematics systems 104 may be communicatively coupled to the fleet monitoring cloud platform 106. The fleet monitoring cloud platform 106 may represent distributed computing resources, software, platform or infrastructure services which may enable data handling, data processing, data management, and/or analytical operations on the data exchanged & transacted amongst the EV fleets 102. In accordance with some example embodiments, the data collected by the OEM telematics systems 104 is uploaded to the fleet monitoring cloud platform 106 for processing. Further, in accordance with some example embodiments, the fleet monitoring cloud platform 106 processes data associated with the one or more EV batteries. In this regard, the fleet monitoring cloud platform 106 also derives the insights associated with the data, and/or the like. Also, in some example embodiments, the fleet monitoring cloud platform 106 may generate one or more opportunities and/or corrective actions based on the derived insights. Additionally, in some example embodiments, the fleet monitoring cloud platform 106 may transmit the one or more opportunities and/or corrective actions to a respective OEM telematics system of the one or more OEM telematics systems 104. Also, in some example embodiments, the fleet monitoring cloud platform 106 may transmit the insights, the one or more opportunities, and/or corrective actions to a mobile device associated with personnel in a facility (i.e. fleet manager).

In some example embodiments, the one or more OEM telematics systems 104 may operate as intermediary node to transact data between the EV fleets 102 and/or the fleet monitoring cloud platform 106. In some example embodiments, each of the one or more OEM telematics systems 104 is capable of processing and/or filtering the collected data so as to be compatible with the fleet monitoring cloud platform 106. In some example embodiments, each of the OEMs may comprise a respective gateway to transact data between a respective EV fleet 102 and/or the fleet monitoring cloud platform 106. Accordingly, in some example embodiments, gateway may operate as intermediary node to transact data between a respective EV fleet 102 and/or the fleet monitoring cloud platform 106. In some example embodiments, the fleet monitoring cloud platform 106 includes one or more servers that may be programmed to communicate with the one or more EV fleets 102 and to exchange data as appropriate. The fleet monitoring cloud platform 106 may be a single computer server or may include a plurality of computer servers. In some example embodiments, the fleet monitoring cloud platform 106 may represent a hierarchal arrangement of two or more computer servers, where perhaps a lower level computer server (or servers) processes telemetry data, for example, while a higher-level computer server oversees operation of the lower level computer server or servers.

The OEM telematics systems 104 are integral components that collect and transmit data from the EV fleets 102 to the fleet monitoring cloud platform 106. The OEM telematics systems 104 may also provide additional diagnostic information about the EV's operational status to the fleet monitoring cloud platform 106. The fleet monitoring cloud platform 106 processes the collected data from each EV to perform various tasks, such as aggregating data on battery performance, calculating the measured capacity of each EV's battery, and evaluating the state of health (SoH) of the EV batteries.

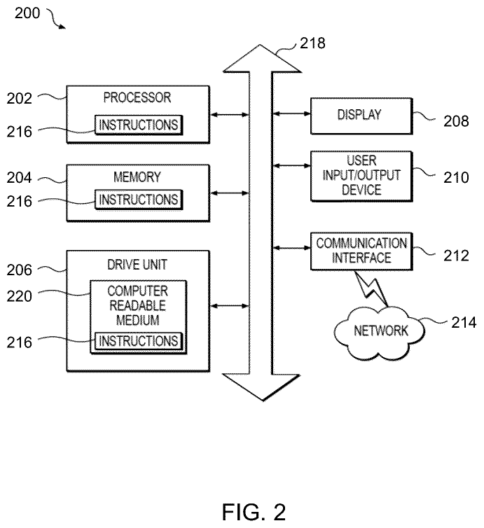

FIG. 2 illustrates a schematic diagram showing an implementation of a controller 200 that may execute techniques in accordance with one or more example embodiments described herein. The controller 200 may include a set of instructions that may be executed to cause the controller 200 to perform any one or more of the methods or computer-based functions disclosed herein. The controller 200 may operate as a standalone device or may be connected, e.g., using a network, to other computer systems or peripheral devices.

In a networked deployment, the controller 200 may operate in the capacity of a server or as a client in a server-client user network environment, or as a peer computer system in a peer-to-peer (or distributed) network environment. The controller 200 may also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 200 may be implemented using electronic devices that provide voice, video, or data communication. Further, while the controller 200 is illustrated as a single system, the term “system” shall also be taken to include any collection of systems or sub-systems that individually or jointly execute a set, or multiple sets, of instructions to perform one or more computer functions.

As illustrated in FIG. 2, the controller 200 may include a processor 202, e.g., a central processing unit (CPU), a graphics processing unit (GPU), or both. The processor 202 may be a component in a variety of systems. For example, the processor 202 may be part of a standard computer. The processor 202 may be one or more general processors, digital signal processors, application specific integrated circuits, field programmable gate arrays, servers, networks, digital circuits, analog circuits, combinations thereof, or other now known or later developed devices for analyzing and processing data. The processor 202 may implement a software program, such as code generated manually (i.e., programmed).

The controller 200 may include a memory 204 that may communicate via a bus 218. The memory 204 may be a main memory, a static memory, or a dynamic memory. The memory 204 includes, but may not be limited to, computer readable storage media such as various types of volatile and non-volatile storage media, including but may not be limited to, random access memory, read-only memory, programmable read-only memory, electrically programmable read-only memory, electrically erasable read-only memory, flash memory, magnetic tape or disk, optical media and the like. In one implementation, the memory 204 includes a cache or random-access memory for the processor 202. In alternative implementations, the memory 204 is separate from the processor 202, such as a cache memory of the processor 202, the system memory, or other memory. The memory 204 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 204 is operable to store instructions executable by the processor 202. The functions, acts or tasks illustrated in the figures or described herein may be performed by the processor 202 executing the instructions stored in the memory 204. The functions, acts or tasks are independent of the particular type of instructions set, storage media, processor or processing strategy and may be performed by software, hardware, integrated circuits, firmware, micro-code and the like, operating alone or in combination. Likewise, processing strategies may include multiprocessing, multitasking, parallel processing and the like.

As shown, the controller 200 may further include a display 208, such as a liquid crystal display (LCD), an organic light emitting diode (OLED), a flat panel display, a solid-state display, a cathode ray tube (CRT), a projector, a printer or other now known or later developed display device for outputting determined information. The display 208 may act as an interface for the user to see the functioning of the processor 202, or specifically as an interface with the software stored in the memory 204 or in the drive unit 206.

Additionally or alternatively, the controller 200 may include an input/output device 210 configured to allow a user to interact with any of the components of controller 200. The input/output device 210 may be a number pad, a keyboard, or a cursor control device, such as a mouse, or a joystick, touch screen display, remote control, or any other device operative to interact with the controller 200.

The controller 200 may also or alternatively include drive unit 206 implemented as a disk or optical drive. The drive unit 206 may include a computer-readable medium 220 in which one or more sets of instructions 216, e.g. software, may be embedded. Further, the instructions 216 may embody one or more of the methods or logic as described herein. The instructions 216 may reside completely or partially within the memory 204 and/or within the processor 202 during execution by the controller 200. The memory 204 and the processor 202 also may include computer-readable media as discussed above.

In some systems, a computer-readable medium 220 includes instructions 216 or receives and executes instructions 216 responsive to a propagated signal so that a device connected to a network 214 may communicate voice, video, audio, images, or any other data over the network 214. Further, the instructions 216 may be transmitted or received over the network 214 via a communication port or interface 212, and/or using a bus 218. The communication port or interface 212 may be a part of the processor 202 or may be a separate component. The communication port or interface 212 may be created in software or may be a physical connection in hardware. The communication port or interface 212 may be configured to connect with a network 214, external media, the display 208, or any other components in controller 200, or combinations thereof. The connection with the network 214 may be a physical connection, such as a wired Ethernet connection or may be established wirelessly as discussed below. Likewise, the additional connections with other components of the controller 200 may be physical connections or may be established wirelessly. The network 214 may alternatively be directly connected to a bus 218.

While the computer-readable medium 220 is shown to be a single medium, the term “computer-readable medium” may include a single medium or multiple media, such as a centralized or distributed database, and/or associated caches and servers that store one or more sets of instructions. The term “computer-readable medium” may also include any medium that is capable of storing, encoding, or carrying a set of instructions for execution by a processor or that cause a computer system to perform any one or more of the methods or operations disclosed herein. The computer-readable medium 220 may be non-transitory, and may be tangible.

The computer-readable medium 220 may include a solid-state memory such as a memory card or other package that houses one or more non-volatile read-only memories. The computer-readable medium 220 may be a random-access memory or other volatile re-writable memory. Additionally or alternatively, the computer-readable medium 220 may include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, may be constructed to implement one or more of the methods described herein. Applications that may include the apparatus and systems of various implementations may broadly include a variety of electronic and computer systems. One or more implementations described herein may implement functions using two or more specific interconnected hardware modules or devices with related control and data signals that may be communicated between and through the modules, or as portions of an application-specific integrated circuit. Accordingly, the present system encompasses software, firmware, and hardware implementations.

The controller 200 may be connected to a network 214. The network 214 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but may not be limited to, TCP/IP based networking protocols. The network 214 may include wide area networks (WAN), such as the Internet, local area networks (LAN), campus area networks, metropolitan area networks, a direct connection such as through a Universal Serial Bus (USB) port, or any other networks that may allow for data communication. The network 214 may be configured to couple one computing device to another computing device to enable communication of data between the devices. The network 214 may generally be enabled to employ any form of machine-readable media for communicating information from one device to another. The network 214 may include communication methods by which information may travel between computing devices. The network 214 may be divided into sub-networks. The sub-networks may allow access to all of the other components connected thereto or the sub-networks may restrict access between the components. The network 214 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations may include distributed processing, component/object distributed processing, and parallel processing. Alternatively, virtual computer system processing may be constructed to implement one or more of the methods or functionalities as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the steps of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

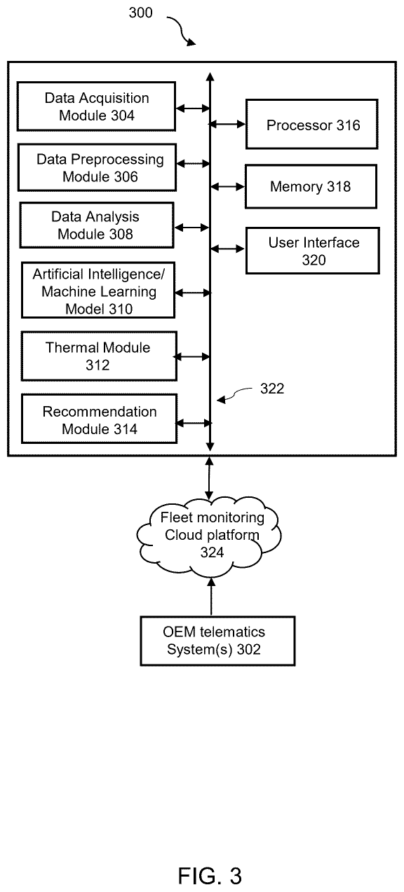

FIG. 3 is an exemplary block diagram illustrating an implementation of the EV Fleet Management System 300, in accordance with one or more embodiments of the present disclosure. In accordance with one or more example embodiments, the EV Fleet Management System 300 described herein monitors the state of health (SoH) of the EV batteries. In accordance with one or more example embodiments, the EV Fleet Management System 300 described herein predicts the residual life of the EV batteries. In accordance with one or more example embodiments, the EV Fleet Management System 300 described herein utilizes data aggregation from EV fleets, applies advanced data analytics and artificial intelligence (AI) and machine learning (ML) models on the aggregated data. In accordance with one or more example embodiments, the EV Fleet Management System 300 described herein integrates fire protection measures, including current sensors and pressure sensors and thermal runaway detection capabilities which further improves the reliability of the EV batteries. In other words, by leveraging the fire protection measures, the EV Fleet Management System 300 may detect potential risks related to overcharging or overheating, allowing for immediate action to prevent fires or catastrophic failures. In accordance with one or more example embodiments, the EV Fleet Management System 300 described herein utilizes the data on various key lithium battery parameters such as, but not limited to, battery temperature, voltage, charging/discharging patterns, and/or environmental conditions to monitor the state of health (SoH) of the EV batteries. In accordance with one or more example embodiments, the EV Fleet Management System 300 described herein specifically analyzes the sub-system/sub-process parameters, e.g., environmental or operational factors (e.g., temperature, pressure, humidity) corresponding to the EV batteries. This makes the analysis more efficient and effective. In accordance with one or more example embodiments, the EV Fleet Management System 300 described herein includes a cloud-based user interface to visualize information on EV charging, Battery electric vehicle (BEV) range capabilities, vehicle GPS, AC/DC charging, and energy utilization. In one or more embodiments, the cloud-based user interface displays the state of health (SoH) and the residual life degradation of the EV batteries and facilitate the generation of one or more corrective actions using the AI/ML models. Hence, the one or more corrective actions could be timely performed by the fleet managers. In accordance with one or more example embodiments, the EV Fleet Management System 300 described herein identifies one or more factors corresponding to the EV batteries that are causing degradation of the EV batteries. The present disclosure could be utilized in real time as new data is entered into the EV Fleet Management System 300.

In this regard, the EV Fleet Management System 300 receives data corresponding to one or more parameters related to the EV batteries. The one or more parameters include current, state of charge (SOC) or EV battery level, battery max/min voltage, battery Max/Min/Median temperature, ambient temperature, charging state (AC/DC/not charging), voltage, power in and out of the battery/on-board charger, energy in and out of the battery/on-board charger, power in and out of the propulsion system, energy in and out of the propulsion system, energy consumption, vehicle-reported battery capacity, odometer readings (distance traveled), charging status, altitude, vehicle tracking and location details, and other vehicle health indicators. The EV Fleet Management System 300 aggregates the data associated with each of the plurality of EV batteries in the fleet monitoring cloud platform. The EV Fleet Management System 300 calculates a measured capacity (MC) of the EV battery based on the aggregated data. The EV Fleet Management System 300 determines a usable original capacity (OC) of the EV battery. The usable original capacity indicates an initial maximum capacity of the EV battery when it was new, as provided by the battery manufacturer. The EV Fleet Management System 300 determines the current state of health (SoH) of the EV battery based on the measured capacity (MC) and the usable original capacity (OC) of the battery. The EV Fleet Management System 300 determines a degradation rate of the EV battery based on one or more historical charging cycles and one or more environmental conditions. The EV Fleet Management System 300 determines the residual life of the EV battery based on the degradation rate of the EV battery, the current state of health (SoH) of the battery, and the one or more parameters related to the EV battery. The EV Fleet Management System 300 generates one or more recommendations including the one or more corrective actions associated with the at least one EV battery. The EV Fleet Management System 300 displays the one or more recommendations on the user interface of the display device.

The present invention offers several valuable insights that can significantly improve battery performance and extend the overall lifespan of these costly assets. For example, the EV Fleet Management System 300 optimizes energy usage and enables more effective predictive maintenance, significantly reducing costs associated with unexpected battery failures and replacements. The EV Fleet Management System 300 provides an in-depth understanding of battery state of health (SoH). Whereas in another example, the EV Fleet Management System 300 predicts residual life of the EV battery by analyzing historical data using one or more AI/ML algorithms. This proactive approach helps identify problematic areas. Further, the EV Fleet Management System 300 indicates how specific variables such as, but not limited to a number of charging cycles, calendar life, temperature, depth of discharge, charging practices, humidity, mechanical stress, storage, environmental factors, and/or like affect health of the EV batteries allowing for focused improvements on the most influential factors. Accordingly, the EV Fleet Management System 300 facilitates a practical application of monitoring health and residual life of EV batteries consistently and identifying and addressing the issues promptly. Further, the use of the one or more ML algorithms prevents recurring issues. Therefore, the EV Fleet Management System 300 identifies root causes of issues, predicting potential factors, providing actionable recommendations, enabling real-time monitoring, and supporting continuous process optimization and improvement.

In an example embodiment the EV Fleet Management System 300 is a server system (e.g., a server device) that facilitates a data analytics platform between one or more computing devices, one or more data sources, and/or one or more EV vehicles. In one or more example embodiments, the EV Fleet Management System 300 is a device with one or more processors and a memory. Also, in some example embodiments, the EV Fleet Management System 300 is implementable via the fleet monitoring cloud platform 106. The EV Fleet Management System 300 is implementable in one or more facilities with large EV fleets, for example, but not limited to, private organizations and government organizations such as schools, hospitals, warehouses, factories, airports, corporate fleets, and/or like.

In some example embodiments, the EV Fleet Management System 300 comprises one or more components and/or sub-systems such as OEM telematics system(s) 302, a data acquisition module 304, a data preprocessing module 306, a data analysis module 308, an artificial intelligence/machine learning (AI/ML) model 310, a thermal module 312, a recommendation module 314, and/or a user interface 320. Additionally, in one or more example embodiments, the EV Fleet Management System 300 comprises a processor 316 and/or memory 318. In one or more example embodiments, one or more components and/or sub-systems of the EV Fleet Management System 300 may be communicatively coupled to the processor 316 and/or the memory 318 via a bus 322. In certain example embodiments, one or more aspects of the EV Fleet Management System 300 (and/or other systems, apparatuses and/or processes disclosed herein) constitute executable instructions embodied within a computer-readable storage medium (e.g., the memory 318). For instance, in an example embodiment, the memory 318 stores computer executable component and/or executable instructions (e.g., program instructions). Furthermore, the processor 316 facilitates execution of the computer executable components and/or the executable instructions (e.g., the program instructions). In an example embodiment, the processor 316 is configured to execute instructions stored in memory 318 or otherwise accessible to the processor 316.

The processor 316 is a hardware entity (e.g., physically embodied in circuitry) capable of performing operations according to one or more embodiments of the disclosure. Alternatively, in an example embodiment where the processor 316 is embodied as an executor of software instructions, the software instructions configure the processor 316 to perform one or more algorithms and/or operations described herein in response to the software instructions being executed. In an example embodiment, the processor 316 is a single core processor, a multi-core processor, multiple processors internal to the EV Fleet Management System 300, a remote processor (e.g., a processor implemented on a server), and/or a virtual machine. In certain example embodiments, the processor 316 is in communication with the memory 318, the OEM telematics system(s) 302, the data acquisition module 304, the data preprocessing module 306, the data analysis module 308, the AI/ML model 310, the thermal module 312, the recommendation module 314, and/or the user interface 320 via the bus 322 to, for example, facilitate transmission of data between the processor 316, the memory 318, the OEM telematics system(s) 302, the data acquisition module 304, the data preprocessing module 306, the data analysis module 308, the AI/ML model 310, the thermal module 312, the recommendation module 314, and/or the user interface 320. In some example embodiments, the processor 316 may be embodied in a number of different ways and, in certain example embodiments, includes one or more processing devices configured to perform independently. Additionally or alternatively, in one or more example embodiments, the processor 316 includes one or more processors configured in tandem via the bus 322 to enable independent execution of instructions, pipelining of data, and/or multi-thread execution of instructions.

The memory 318 is non-transitory and includes, for example, one or more volatile memories and/or one or more non-volatile memories. In other words, in one or more example embodiments, the memory 318 is an electronic storage device (e.g., a computer-readable storage medium). The memory 318 is configured to store information, data, content, one or more applications, one or more instructions, or the like, to enable the EV Fleet Management System 300 to carry out various functions in accordance with one or more embodiments disclosed herein. In accordance with some example embodiments described herein, the memory 318 may correspond to an internal or external memory of the EV Fleet Management System 300. In some examples, the memory 318 may correspond to a database communicatively coupled to the EV Fleet Management System 300. As used herein in this disclosure, the term “component,” “system,” and the like, is a computer-related entity. For instance, “a component,” “a system,” and the like disclosed herein is either hardware, software, or a combination of hardware and software. As an example, a component is, but is not limited to, a process executed on a processor, a processor circuitry, an executable component, a thread of instructions, a program, and/or a computer entity.

In one or more embodiments, the OEM telematics system(s) 302 may represent primary data sources within the EV Fleet management System 300. The OEM telematics systems 302 collect real-time telemetry data from each EV within the EV fleet. The OEM telematics systems 302 include sensors that monitor critical key lithium battery parameters such as state of charge (SoC), charging cycles, temperature variations, voltage fluctuations, and other vehicle diagnostics. The OEM telematics system(s) 302 transmit this data to the fleet monitoring cloud platform 324, where it is aggregated for analysis. Each OEM telematics system 302 includes various telematics devices installed in the EV. The telematics devices enable the collection and transmission of the telemetry data through wireless networks, leveraging the vehicle's onboard modem and diagnostics (such as OBDII). The OEM telematics systems 302 combine a variety of technologies, including IoT-based vehicle telematics, cloud platforms, hardware, and software solutions, which allow for seamless integration of multiple sensors, GPS tracking, and fleet management tools. One or more parameters captured by the OEM telematics system(s) 302 include battery data (such as battery health, charge/discharge cycles, and energy usage), temperature fluctuations, voltage changes, diagnostic information during both charging and discharging phases, and/or like. The one or more parameters are vital for maintaining the health and efficiency of the EV fleet, as they provide continuous insights into the status of each EV's battery and operational performance.

In one or more embodiments, the data acquisition module 304 may continuously acquire and aggregate the data corresponding to the one or more parameters associated with the EV batteries at the fleet monitoring cloud platform 324. The data acquisition module 304 facilitates the collection of raw data from a variety of sources, such as the one or more sensors, GPS systems, and the OBDII devices. The data acquisition module 304 ensures that all relevant data from the EVs is acquired and transmitted to the data preprocessing module 306 for further processing. The data acquisition module 304 includes mechanisms for obtaining the real-time data associated with the EV batteries from the OEM telematics system(s) 302.

In one or more embodiments, the data preprocessing module 306 plays a crucial role in storing the real-time data and handles integration of the real-time data from various OEM telematics system(s) 302 in the EV Fleet Management System 300. The data preprocessing module 306 uses data pipelines and streaming technologies for real-time data processing. This ensures compatibility with various OEM telematics system(s) 302 and smooth integration into the EV Fleet Management System 300. This also involves configuring data transfer protocols and ensuring compatibility between the data acquisition module 304 and the data preprocessing module 306. The data preprocessing module 306 includes a time-series database that can efficiently handle large volumes of data, especially when data is collected in real time over a period. In one or more embodiments, the data preprocessing module 306 performs data cleaning to remove or correct erroneous or incomplete data and subsequently performs data normalization on the incoming data to ensure consistency and reliability of the data for further analysis. Normalization standardizes the data, especially when multiple sources are involved with potentially different units or scales of measurement. Therefore, the data preprocessing module 306 ensures that real-time data is properly aggregated, cleaned, and normalized for subsequent analysis such as machine learning modeling or decision-making within the EV Fleet Management System 300.

In one or more embodiments, the data analysis module 308 applies custom calculations or formula-based calculations and advanced artificial intelligence (AI) and machine learning (ML) techniques to determine state of health (SoH) and performance of electric vehicle (EV) batteries within a fleet of EVs. In one or more embodiments, the data analysis module 308 calculates the measured capacity (MC) of the EV battery based on the data received from the data preprocessing module 306. The Measured capacity (MC) is that which the vehicle makes accessible for storage and vehicle operations, which may be different from what is physically available (actual). The measured capacity (kWh) is the mean for a normal distribution based on the recent 90-day rolling average. In one or more embodiments, the measured capacity (MC) can be calculated with 90% confidence. In this regard, the data analysis module 308 determines a state of charge (SoC) start percentage at start of a charging session of the EV battery and a state of charge (SoC) end percentage at end of the charging session of the EV battery. The data analysis module 308 calculates energy transferred during the charging session of the EV battery. Accordingly, the data analysis module 308 calculates the measured capacity (MC) of the battery based on a ratio of the energy transferred (TC) during the charging session and a difference between the SoC start percentage (SoC start %) and the SoC end percentage (SoC end %). Further, the data analysis module 308 determines the usable original capacity (OC) of the EV battery. The usable original capacity (OC) indicates an initial maximum capacity of the EV battery when it was new. The usable original capacity (OC) is the original battery capacity of the EV as stated by the manufacturer. The usable original capacity (OC) may be determined from OEM specifications or large sample of EVs with the same make, model, year, and averaged with 90% confidence. The data analysis module 308 may use historical data communicated by the EVs to detect the usable original capacity (OC). The data analysis module 308 calculates the current state of health (SoH) of the EV battery based on the ratio of the measured capacity (MC) and the usable original capacity (OC) of the EV battery.
MC=TC/(SOC end %−SOC start %)
SoH %=100*(MC)/(OC)

In one or more embodiments, let's assume:
SoC Start %=19
SoC End %=79
Actual Energy Transferred=48.7 Kwh
MC=(48.7*100)/(79−19)=81.2 Kwh
Usable original capacity (OB)=93 Kwh
State of Health (SoH)=100*(81.2/93)=87%

In one or more embodiments, the data analysis module 308 determines a degradation rate of the EV battery based on one or more historical charging cycles and one or more environmental conditions. Further, the data analysis module 308 determines the specific variables such as, but not limited to a number of charging cycles, calendar life, temperature, depth of discharge, charging practices, humidity, mechanical stress, storage, environmental factors, and/or like affect the state of health (SoH) of the EV batteries. Thus, the data analysis module 308 allows focused improvements on the most influential factors. In one or more embodiments, the data analysis module 308 determines the residual life of the EV battery based on the degradation rate of the EV battery, the current state of health (SoH) of the battery, and the one or more parameters related to the EV battery. In one or more embodiments, while using a linear model for degradation, if the battery degrades at a constant rate, each percentage decrease in SOH corresponds to 10% of the battery's initial life expectancy. Given a current SOH of 80%, the residual life is 8 years. So, based on this linear degradation assumption, the residual life of the EV battery is 8 years as shown below:
Residual Life of EV battery=10*(80/100)=8 years

In one or more embodiments, the data analysis module 308 determines the residual life of the EV battery based on a more detailed approach. The data analysis module 308 determines the residual life of the EV battery based on a residual state of health (SoH) of the EV battery, a battery non-usable SOC, and the degradation rate of the EV battery. The Residual SoH is remaining battery health which is usable detected available battery capacity out of total usable original capacity. The battery non-usable SOC could be defined as a limit after which the capacity of the battery reaches to non-usable limit and cannot be used for extracting charge for the EV. To calculate the residual SoH, the data analysis module 308 determines an initial range and a current range of the EV. The residual SoH is calculated as a ratio of the current range and the initial range of the EV.
Residual SOH=(Current Range/Initial Range)

Let's assume the initial range of the EV is 150 miles and the initial SoH of the EV battery is 100%. If degradation of the EV battery occurs for 5 years at a rate of 2.3%, then the current range of the EV is 133 miles. Based on this, the residual SoH is 88%. Further, the data analysis module 308 determines the battery non-usable SoC. The battery non-usable SoC could be a predefined limit. The residual life using this approach is calculated as 5.6 years when the battery's SoH reaches 75% as shown below:
Residual Life of EV battery=(Residual SoH−Battery non-usable SoC)/Degradation Rate
Residual Life of EV battery=(88%−75%)/(2.3%)=5.6 years

In one or more embodiments, the data analysis module 308 calculates the current SoH of the EV battery based on ampere hours delivered per SoC. Battery capacity is expressed in Ah or kWh. Ampere hour per SoC is calculated based on each charge cycle. Rated Ampere Hour per SoC could be determined from the data acquired from the OEM telematics system(s) 302.

% Difference=(Ah per SoC rated−Ah per SoC calculated)/(Ah per SoC rated) indicates the capacity hold by the EV battery during the charging session. As the EV battery deteriorates, the capacity of EV battery reduces significantly. Percentage difference could be monitored to indicate the battery capacity. If percentage difference is 15%, then a warning may be issued. If percentage difference is above 25%, then the battery may require Maintenance.

In one or more embodiments, the data analysis module 308 calculates the current SoH of the EV battery based on a baseline method. According to the baseline method, for a given capacity, the EV battery might take ‘n’ mins to fully charge. A baseline ‘b’ mins can be derived for the average time taken to charge a certain type of EV battery. Based on the variation from baseline (‘b’−‘n’), a range can be defined to indicate the current SoH of the EV battery. This may be shown as below:
(b−n)<=x: Battery SoH is good, where x is configurable
x<(b−n)<=y: Battery SoH is average and trigger an alert, where x and y are configurable
(b−n)>=z: Battery SoH is bad and generate an alarm, where z is configurable

In one or more embodiments, the data analysis module 308 monitors the charging status of the battery. The data analysis module 308, using the AI/ML model 310, predicts an optimal charging time of the battery based on the current state of health (SoH), the degradation rate, and the historical data of the battery. In one or more embodiments, the data analysis module 308 can detect early signs of battery degradation or faults, preventing overcharging and discharging issues and alert the fleet managers about the current SoH of the battery in integration with smart charging ensures optimal performance, vehicle uptime, extended battery life, and user confidence.

In one or more embodiments, the AI/ML model 310 may include one or more AI/ML algorithms. The AI/ML model 310 predicts the residual life of EV batteries, estimate degradation rates of EV batteries, forecast future battery failures, and optimize maintenance schedules. In one or more embodiments, the AI/ML model 310 predicts the residual life of EV batteries using capacity fade rate and real-time site data from the OEM telematics system(s) 302. The AI/ML model 310 could be, but not limited to, linear regression model, decision tree model, random forest model, and support vector machines (SVM) model. The AI/ML model 310 is trained based on historical data to predict battery degradation. The AI/ML model 310 analyzes past battery data to learn how various factors, such as charging patterns, discharge time, charging cycles, temperature variations, maximum voltage, minimum voltage, and operational conditions, affect the state of health (SoH) of the EV batteries. The AI/ML model 310 is continuously trained with new data, improving its predictive capabilities over time, which helps fleet managers make informed decisions about battery maintenance schedules, replacement, and fleet operation. In one or more embodiments, the AI/ML model 310 improves the accuracy of the state of health (SoH) and residual life predictions. In one or more embodiments, the AI/ML model 310 helps identify the root causes of battery degradation issues, making it easier to pinpoint where corrective actions are needed. This identification of the exact point of failure allows for targeted corrective actions. The AI/ML model 310 is trained based on the historical data and the real-time data. For model creation, the dataset is split into training dataset and testing dataset, typically using 80% for training the model and 20% for testing the model's performance. During the testing phase, the model's performance is evaluated based on the testing dataset. A high accuracy indicates that the model effectively predicts the inspection outcomes. The Accuracy of the model is determined using the formula:
Accuracy=Number of Accurate Predictions/Total Number of Predictions
If the accuracy meets the predetermined threshold, further analysis is performed. If not, the features may be re-evaluated by collecting more data.

Further, in some example embodiments, the EV Fleet Management System 300 may utilize the AI/ML model 310 model to provide the one or more insights. Also, in some example embodiments, the AI/ML model 310 may be trained with one or more datasets to facilitate provision of the one or more insights. In this regard, the one or more datasets may be related to the historical data. Additionally, in some example embodiments, the one or more insights may be provided as feedback. In this regard, the AI/ML model 310 may learn over time to provide improved and accurate insights. In some example embodiments, the AI/ML model 310 may be trained with one or more new datasets on a regular basis or for a pre-defined time interval to improve relevancy of insights. The EV Fleet Management System 300 implements mechanisms for continuous improvement based on user feedback such as analyzing the historical data to optimize the AI/ML model 310.

In one or more embodiments, the thermal module 312 monitors temperature variations in the EV batteries during charging, discharging, and idle states. Battery temperature plays a critical role in the health and longevity of the battery, with extreme temperatures (either too high or too low) accelerating degradation. The thermal module 312 collects real-time temperature data from the EVs using current sensors and pressure sensors and ensures that the batteries are operating within safe thermal ranges. The thermal module 312 integrates fire protection measures, including the current sensors and pressure sensors and thermal runaway detection capabilities which further improves the reliability of the EV batteries. The thermal module 312 detects thermal runaway or overheating issues, alerting the fleet manager to potential problems before they cause significant damage to the battery or vehicle. In other words, by leveraging the fire protection measures, the thermal module 312 may detect potential risks related to overcharging or overheating, allowing for immediate action to prevent fires or catastrophic failures. By managing temperature data, the thermal module 312 enhances the overall safety and reliability of the EV fleet.

In one or more embodiments, the recommendation module 314 generates one or more recommendations including the one or more corrective actions associated with the EV battery within the EV fleet. The recommendation module 314 suggests the one or more corrective actions to resolve the identified issues. The one or more corrective actions may include initiating maintenance, replacing batteries, optimizing charging schedules based on the state of health (SoH) and degradation patterns, modifying vehicle operations, such as adjusting charging frequency, to extend battery life, and/or like. In an embodiment, the recommendation module 314 ensures that the most relevant corrective actions are suggested. This reduces unnecessary interventions and focuses on the areas that will optimize fleet performance, reduce costs, and improve vehicle uptime by offering data-driven recommendations tailored to each vehicle's specific conditions. By addressing the issues early, the recommendation module 314 may help in extending the battery lifespan and reducing cost.

Further, in some example embodiments, the one or more recommendations and/or insights may be transmitted to the user interface 320. In one or more embodiments, the user interface 320 is configured to display the one or more recommendations and/or the one or more insights. In another example, the one or more root causes of the degradation issues may be rendered on the user interface 320. The one or more recommendations may be presented in the form reports, dashboard, descriptions, charts, trends, graphs, and/or like. This may include bar charts, pie charts, or line graphs. In one or more example embodiments, the one or more insights include, but may not be limited to, the status of the one or more corrective actions and/or like. In another embodiment, one or more notifications may be transmitted to the user interface 320. The one or more notifications may correspond to a faulty battery notification. The one or more notifications include, but may not be limited to, replacing batteries, optimizing charging schedules, modifying vehicle operations, and/or like. The user interface 320 may correspond to an interface of a device associated with the fleet manager. In some example embodiments, one or more alert signals may be generated based on the one or more insights. In some example embodiments, the one or more alert signals may be transmitted to the user interface 320. In this regard, in some example embodiments, one or more notifications may be generated on the user interface 320 based on the one or more alert signals. Accordingly, in some examples, the one or more notifications may be visual notifications. Whereas, in some examples, the one or more notifications may be audio notifications. Also, in some example embodiments, the user interface 320 may allow the fleet manager to provide input and/or feedback regarding the one or more insights. For example, an input may correspond the fleet manager selecting a corrective action. In this regard, the one or more insights may be rendered as visualizations, such as on the user interface 320, to help the personnel such as the fleet manager to identify the one or more insights and thereby undertake appropriate actions.

In some example embodiments, the one or more components, one or more sub-systems, processor 316 and/or memory 318 of the EV Fleet Management System 300 may be communicatively coupled to the fleet monitoring cloud platform 324 over a network. In this regard, the one or more components, processor 316 and/or memory 318 along with the fleet monitoring cloud platform 324 monitors the state of health (SoH) and the residual life of the EV batteries. In some example embodiments, the network may be for example, a Wi-Fi network, a Near Field Communications (NFC) network, a Worldwide Interoperability for Microwave Access (WiMAX) network, a personal area network (PAN), a short-range wireless network (e.g., a Bluetooth® network), an infrared wireless (e.g., IrDA) network, an ultra-wideband (UWB) network, an induction wireless transmission network, a BACnet network, a NIAGARA network, a NIAGARA CLOUD network, and/or another type of network. In some example embodiments, the data received from the OEM telematics system(s) 302 may be transmitted to the fleet monitoring cloud platform 324. In some example embodiments, the fleet monitoring cloud platform 324 may be configured to perform one or more operations/functionalities of the one or more components, one or more sub-systems, processor 316 and/or memory 318 of the EV Fleet Management System 300.

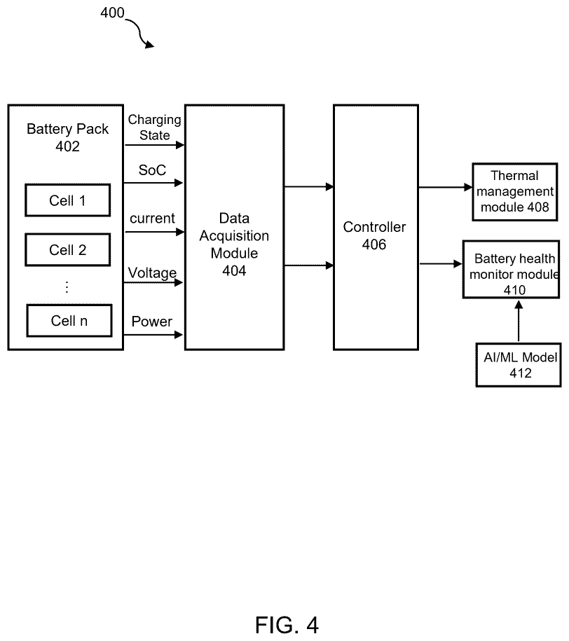

FIG. 4 is an exemplary block diagram illustrating monitoring state of health (SoH) of EV batteries in accordance with one or more embodiments of the present disclosure. In one or more embodiments, an EV Fleet Management System 400 includes a battery pack 402, a data acquisition module 404, a controller 406, a thermal management module 408, a battery health monitor module 410, and/or an AI/ML Model 412.

In one or more embodiments, the battery pack 402 is the core component of the Electric Vehicle (EV), composed of multiple battery cells 1, 2, . . . n arranged to provide the necessary power for EV operations. Each cell has its own voltage and capacity characteristics. The battery pack 402 as a whole manages the power distribution and storage for the EV. The battery pack 402 contains multiple cells connected in series and parallel to achieve the required voltage and capacity. These cells are continuously monitored to track their individual performance, health, and operational parameters, which will be used for the health assessment and maintenance schedule.

In one or more embodiments, the data acquisition module 404 may continuously acquire and aggregate the data corresponding to the one or more parameters associated with the EV batteries at the fleet monitoring cloud platform. The data acquisition module 304 includes mechanisms for obtaining the real-time data associated with the EV batteries from the OEM telematics system(s). The data acquisition module 304 facilitates the collection of raw data from a variety of sources, such as the one or more sensors, GPS systems, and the OBDII devices. In one or more embodiments, the OEM telematics system(s) may represent primary data sources within the EV Fleet management System 400. The OEM telematics systems collect real-time telemetry data from each EV within the EV fleet. The OEM telematics systems include sensors that monitor critical key lithium battery parameters such as state of charge (SoC), charging cycles, temperature variations, voltage fluctuations, and other vehicle diagnostics. The OEM telematics system(s) transmit this data to the fleet monitoring cloud platform, where it is aggregated for analysis. Each OEM telematics system includes various telematics devices installed in the EV. The telematics devices enable the collection and transmission of the telemetry data through wireless networks, leveraging the vehicle's onboard modem and diagnostics (such as OBDII). The OEM telematics systems combine a variety of technologies, including IoT-based vehicle telematics, cloud platforms, hardware, and software solutions, which allow for seamless integration of multiple sensors, GPS tracking, and fleet management tools. One or more parameters captured by the OEM telematics system(s) include battery data (such as battery health, charge/discharge cycles, and energy usage), temperature fluctuations, voltage changes, diagnostic information during both charging and discharging phases, and/or like. The one or more parameters are vital for maintaining the health and efficiency of the EV fleet, as they provide continuous insights into the status of each EV's battery and operational performance.

In one or more embodiments, the battery health monitor module 410 applies custom calculations or formula-based calculations and advanced artificial intelligence (AI) and machine learning (ML) techniques to determine state of health (SoH) and performance of electric vehicle (EV) batteries within a fleet of EVs. In one or more embodiments, the battery health monitor module 410 determines a degradation rate of the EV battery based on one or more historical charging cycles and one or more environmental conditions. Further, the battery health monitor module 410 determines the specific variables such as, but not limited to a number of charging cycles, calendar life, temperature, depth of discharge, charging practices, humidity, mechanical stress, storage, environmental factors, and/or like affect the state of health (SoH) of the EV batteries. In one or more embodiments, the battery health monitor module 410 determines the residual life of the EV battery based on the degradation rate of the EV battery, the current state of health (SoH) of the battery, and the one or more parameters related to the EV battery.

In one or more embodiments, the thermal management module 408 regulates the temperature of the battery pack 402 using thermal sensors to monitor the temperature of individual cells in the battery pack 402 to ensure the battery operates within safe thermal limits. If temperature rise is too high or drop too low, the controller 406 adjusts the cooling or heating systems (e.g., fans, liquid cooling, or heating pads) to maintain the battery pack 402 within an optimal temperature range. Proper thermal management enhances battery lifespan and prevents issues like thermal runaway or overheating.

In one or more embodiments, the AI/ML Model 412 plays a crucial role by using historical data and real-time data to predict battery degradation, forecast failures, and optimize maintenance decisions. The AI/ML Model 412 uses machine learning algorithms (such as linear regression, decision trees, random forest, or support vector machines) to analyze the collected data. The AI/ML Model 412 may learn from patterns in battery usage, charging cycles, temperature variations, and operational conditions, improving its predictive capabilities over time. Based on its predictions, the AI/ML model 412 may offer recommendations such as maintenance schedules, battery replacements, and optimizing charging/discharging patterns. The AI/ML model 412 is continuously updated with new data, which allows it to adapt and refine its forecasts for better accuracy. Based on the data from the Battery Health Monitoring Module, the AI/ML model 412 makes predictions about the battery's future performance, such as when a failure might occur, the remaining usable life of the battery, and when maintenance or replacement should occur. It can recommend actions like adjusting charging schedules, replacing battery, or optimizing vehicle operations.

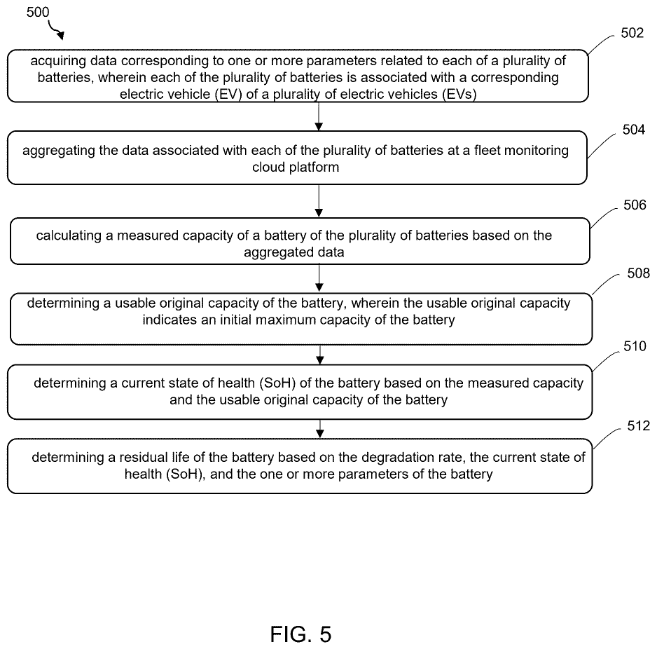

FIG. 5 is a flowchart illustrating a method described in accordance with one or more embodiments of the present disclosure. An exemplary flowchart 500 describes an exemplary method for determining the state of health (SoH) and the residual life of the EV batteries within the EV fleets via the EV Fleet Management System 300. At step 502, the EV Fleet Management System 300 includes means, such as the OEM telematics system 302 to acquire data corresponding to one or more parameters related to each of a plurality of batteries. Each of the plurality of batteries is associated with a corresponding EV of a plurality of EVs. At step 504, the EV Fleet Management System 300 includes means, such as the fleet monitoring cloud platform 324 to aggregate the data associated with each of the plurality of batteries. Further, at steps 506, 508, and 510, the EV Fleet Management System 300 includes means, such as the data analysis module 308, to calculate a measured capacity and a usable original capacity of the battery and determine a current state of health (SoH) of the battery based on the measured capacity and the usable original capacity of the battery. Furthermore, at step 512, the EV Fleet Management System 300 includes means, such as the data analysis module 308, to determine a residual life of the battery based on the degradation rate, the current state of health (SoH), and the one or more parameters of the battery.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the supply management system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

1. A system, comprising:
at least one processor; and
a memory communicatively coupled to the at least one processor, wherein the memory comprises one or more instructions which when executed by the at least one processor, cause the at least one processor to:
acquire data corresponding to one or more parameters related to each of a plurality of batteries, wherein each of the plurality of batteries is associated with a corresponding electric vehicle (EV) of a plurality of electric vehicles (EVs);
aggregate the data associated with each of the plurality of batteries at a fleet monitoring cloud platform;
calculate a measured capacity of a battery of the plurality of batteries based on the aggregated data;
determine a usable original capacity of the battery, wherein the usable original capacity indicates an initial maximum capacity of the battery; and
determine a current state of health (SoH) of the battery based on the measured capacity and the usable original capacity of the battery.

2. The system of claim 1, wherein the fleet monitoring cloud platform is integrated with a plurality of OEM vehicle telematics systems to collect the data from different models and manufacturers of the plurality of EVs.

3. The system of claim 1, wherein the processor is further configured to:
determine a state of charge (SoC) start percentage at start of a charging session of the battery;
determine a state of charge (SoC) end percentage at end of the charging session of the battery;
calculate energy transferred during the charging session of the battery; and
calculate the measured capacity of the battery based on the energy transferred during the charging session and a difference between the SoC start percentage and the SoC end percentage.

4. The system of claim 3, wherein the current state of health (SoH) is determined as:
100*(MC)/(OC),
wherein OC is the usable original capacity of the battery and MC is the measured capacity during charging of the battery.

5. The system of claim 3, wherein the measured capacity (MC) is calculated based on a rolling average over a predetermined time period.

6. The system of claim 1, wherein the processor is further configured to analyze each of charging and discharging pattern, temperature variations, and voltage changes corresponding to the battery.

7. The system of claim 1, wherein the processor is further configured to:
determine a degradation rate of the battery based on one or more historical charging cycles and one or more environmental conditions; and
determine a residual life of the battery based on the degradation rate of the battery, the current state of health (SoH) of the battery, and the one or more parameters related to the battery.

8. The system of claim 1, wherein the processor is further configured to predict, using an artificial intelligence/machine learning (AI/ML) model, a residual life of the battery based on historical data corresponding to the plurality of batteries.

9. The system of claim 8, wherein the AI/ML model comprises at least one of linear regression, decision tree, random forest, and support vector machine.

10. The system of claim 1, wherein the processor is further configured to:
monitor a charging status of the battery; and
predict, using an AI/ML model, an optimal charging time of the battery based on the current state of health (SoH), a degradation rate, and historical data of the battery.

11. The system of claim 1, wherein the processor is further configured to:
detect, via one or more sensors, at least one of overcharging, overheating, and thermal runaway corresponding to the battery; and
generate one or more alerts based on the detection of at least one of the overcharging, the overheating, and the thermal runaway corresponding to the battery.

12. The system of claim 1, wherein the fleet monitoring cloud platform includes a mobile application interface to access real-time data on the current state of health (SoH) of the battery.

13. The system of claim 1, wherein the processor is further configured to predict, using an AI/ML model, maintenance needs of the battery based on the current state of health (SoH) of the battery.

14. A method, comprising:
acquiring data corresponding to one or more parameters related to each of a plurality of batteries, wherein each of the plurality of batteries is associated with a corresponding electric vehicle (EV) of a plurality of electric vehicles (EVs);
aggregating the data associated with each of the plurality of batteries at a fleet monitoring cloud platform;
calculating a measured capacity of a battery of the plurality of batteries based on the aggregated data;
determining a usable original capacity of the battery, wherein the usable original capacity indicates an initial maximum capacity of the battery; and
determining a current state of health (SoH) of the battery based on the measured capacity and the usable original capacity of the battery.

15. The method of claim 14, further comprising:
determining a state of charge (SoC) start percentage at start of a charging session of the battery;
determining a state of charge (SoC) end percentage at end of the charging session of the battery;
calculating energy transferred during the charging session of the battery; and
calculating the measured capacity of the battery based on the energy transferred during the charging session and a difference between the SoC start percentage and the SoC end percentage.

16. The method of claim 14, further comprising analyzing each of charging and discharging pattern, temperature variations, and voltage changes corresponding to the battery.

17. The method of claim 14, further comprising:
determining a degradation rate of the battery based on one or more historical charging cycles and one or more environmental conditions; and
determining a residual life of the battery based on the degradation rate of the battery, the current state of health (SoH) of the battery, and the one or more parameters related to the battery.

18. The method of claim 14, further comprising predicting, using an artificial intelligence/machine learning (AI/ML) model, a residual life of the battery based on historical data corresponding to the plurality of batteries.

19. The method of claim 14, further comprising:
detecting, via one or more sensors, at least one of overcharging, overheating, and thermal runaway corresponding to the battery; and
generating one or more alerts based on the detection of at least one of the overcharging, the overheating, and the thermal runaway corresponding to the battery.

20. A non-transitory computer-readable medium having instructions stored thereon that, when executed by at least one processor, cause the at least one processor to perform operations comprising:
acquiring data corresponding to one or more parameters related to each of a plurality of batteries, wherein each of the plurality of batteries is associated with a corresponding electric vehicle (EV) of a plurality of electric vehicles (EVs);
aggregating the data associated with each of the plurality of batteries at a fleet monitoring cloud platform;
calculating a measured capacity of a battery of the plurality of batteries based on the aggregated data;
determining a usable original capacity of the battery, wherein the usable original capacity indicates an initial maximum capacity of the battery; and
determining a current state of health (SoH) of the battery based on the measured capacity and the usable original capacity of the battery.
